(19) United States
(12) Patent Application Publication
(10) Pub. No.: US 2024/0074111 A1
(43) Pub. Date: Feb. 29, 2024

(54) CAGE ASSEMBLIES FOR HIGH-SPEED DATA CONNECTORS

(71) Applicant: Molex, LLC, Lisle, IL (US)

(72) Inventor: Weiming Chen, Pleasanton, CA (US)

(21) Appl. No.: 18/272,349

(22) PCT Filed: Jan. 14, 2022
(86) PCT No.: PCT/IB2022/050281

§ 371 Date: Jul. 14, 2023

Related U.S. Application Data
(60) Provisional application No. 63/137,169, filed on Jan. 14, 2021.

(51) Int. Cl. H05K 7/20

(52) U.S. Cl. CPC H05K 7/20336; H05K 7/20409

(57) ABSTRACT

High-speed data connectors are configured to create thermal transfer paths to transfer thermal energy away from internal connector components and plug-ins transporting high speed data signals. Heat pipes are configured to transfer thermal energy generated by a connector cage assembly and the connected components during operation of the assembly. Heat pipes may be thermally coupled to plug-in modules.

### CROSS-REFERENCE TO RELATED APPLICATION

This application claims priority to U.S. Provisional Application 63/137,169 filed Jan. 14, 2021, which is incorporated herein by reference in its entirety.

### TECHNICAL FIELD

This disclosure relates to the field of connectors, more specifically to structures for high-speed data connectors.

### INTRODUCTION

The transmission of high-speed data signals (e.g., greater than 56 Gigabits per second (Gbps) and in certain cases, between 112 Gbps and 224 Gbps) may cause the temperature of components conducting such signals (e.g., electrical and optical cables) and components (e.g., connectors) connected to the conductors to rise. For example, active electronic processors that are enhancing high-speed data signals will generate heat as a result of their operation. Typically, such active processors will generate an increasing amount of heat with increased signal speed thus necessitating improvements in thermal management corresponding to the signal speed throughput.

Accordingly, it is desirable to provide connectors that include features to transfer and remove thermal energy (e.g., heat).

### SUMMARY

In an embodiment, inventive exemplary connectors may include assemblies and chassis to address and overcome some of the shortcomings of existing connectors.

In more detail, a connector cage assembly, which may be formed of a die cast material, may comprise: sidewalls, a top wall, a bottom wall and a rear wall that define a partially enclosed interior volume of the connector cage assembly; a front face having one or more ports, each port configured to receive one or more connected components (e.g., 2×1 double density (DDQ), small form-factor plug-in modules configured to transport high-speed data signals; and a first cantilevered heat pipe configured to transfer thermal energy generated by the connector cage assembly and the connected components during operation of the assembly and the connected components.

In embodiments, the connector cage assembly may be composed of an aluminum alloy and the first cantilevered heat pipe may be composed of at least copper or a copper alloy or another alloy capable of transferring thermal energy. Alternatively, such a heat pipe may comprise a sealed copper wall, wick structure on an inside wall, and a working fluid, for example.

Further, the connector cage assembly may comprise one or more additional heat pipes, such as a second cantilevered heat pipe configured to transfer thermal energy generated by the connector cage assembly and the connected components during operation of the assembly and the connected components. Similar to the first heat pipe, the additional heat pipe(s) may be composed of at least copper or a copper alloy or another alloy capable of transferring thermal energy. Alternatively, such an additional heat pipe(s) may comprise a sealed copper wall, wick structure on an inside wall, and a working fluid, for example.

The top wall may comprise a surface indentation configured to receive portions of the first cantilevered heat pipe and an exterior opening configured to receive additional portions of the first cantilevered heat pipe. In more detail, in one embodiment the first cantilevered heat pipe may comprise a first portion, a second portion and a third portion (the latter two portions are “additional” portions), where the first portion is configured within an opening of the die cast top wall and the second and third portions are configured within a surface indentation of the die cast top wall. In an embodiment, the third portion may be fixably connected to the die cast top wall while the first and second portions may not be fixably connected to the die cast top wall.

In addition, the sidewalls may include a plurality of fins to transfer thermal energy to air flowing around respective fins. Similarly, the top wall may also comprise a plurality of fins to transfer thermal energy to air flowing around respective fins, where the height of the fins of the die cast, top wall may vary depending upon desired thermal transfer requirements, available space above the connector cage assembly, the manufacturability of die cast cage assembly, and the performance of the assembly. For example, the height of the fins of the top wall may vary between 2.5 to 4.5 millimeters. As can be appreciated, if a die cast process (or something similar) is used, then the fins can be formed integrally with the corresponding wall structure.

In addition to fins, the die cast sidewalls may also comprise a plurality of vents to allow air surrounding the assembly to pass through the vents in order to transfer thermal energy away from interior components of the assembly.

The exemplary assembly may further comprise a first restraining clip to restrain the movement of the first cantilevered heat pipe and to create a thermal path that allows thermal energy to be transferred from the connected components to the first cantilevered heat pipe.

Similarly, the second cantilevered heat pipe may comprise a first portion, a second portion and a third portion, wherein the third portion may be fixably connected to an interior of the assembly and the first and second portions may not be fixably connected to the interior of the assembly. The assembly may comprise a second restraining clip to restrain the movement of the second cantilevered heat pipe and to create a thermal path to allow thermal energy to be transferred from the connected components to the second cantilevered heat pipe.

In addition to connector cage assemblies, the inventors provide inventive chassis. In one embodiment an exemplary chassis may be configured to receive one or more assemblies (e.g., 1×2, DDQ, small form factor assembly), where the chassis may comprise: a support structure configured to receive and securely hold the assemblies. Further, each chassis may comprise a heat sink (composed of an extruded aluminum, for example) comprising a plurality of first fins to transfer thermal energy to air flowing around a respective first fin, one or more cantilevered heat pipes received in the heat sink, each heat pipe comprising a section fixably connected to the heat sink and another section that is not connected to the heat sink, wherein the section that is not connected to the heat sink is configured to contact a plug-in module transporting high-speed data signals, to create a thermal path to transfer thermal energy from the plug-in module to the contacted end section and then to the support structure, and a cage structure (e.g., composed on an extruded aluminum, for example) comprising a plurality of second fins to transfer thermal energy to air flowing around a respective second fin. The chassis can be formed with a die cast or similar process to allow fins to be formed integrally with the supporting structure.

In embodiments, the one or more cantilevered heat pipes may be composed of at least copper or a copper alloy. Alternatively, such heat pipes may comprise a sealed copper wall, wick structure on an inside wall, and a working fluid, for example.

Each of the one or more cantilevered heat pipes may be configured with a minimum bend radius to contact with the plug-in module. In embodiments, the heat sink may comprise one or more surface indentations configured to receive first sections of cantilevered heat pipes and one or more openings configured to receive second, additional sections of the cantilevered heat pipes, where the first sections of the cantilevered heat pipes may be fixably connected to the heat sink and the second, additional sections may not be connected to the heat sink.

The exemplary chassis may further comprise one or more spring structures for each cantilevered heat pipe configured to restrain movement of a respective, cantilevered heat pipe, each spring structure configured to apply a force to a section of a respective cantilevered heat pipe such that the section contacts with the plug-in module to create a thermal path to allow thermal energy to be transferred to the section. In embodiments, the heat sink may be configured with cut-outs between first fin structures to receive the one or more spring structures.

### BRIEF DESCRIPTION OF THE DRAWINGS

The present disclosure is illustrated by way of example and not limited to the accompanying figures in which like reference numerals may refer to similar elements and in which:

FIGS. 1 and 2 depict front and back views, respectively, of an exemplary, connector cage assembly;

FIG. 3 depicts another view of the exemplary assembly in FIGS. 1 and 2;

FIGS. 4 to 6 depict alternative configurations of fins of an exemplary top wall of an assembly;

FIG. 7 depicts a view of the exemplary assembly in FIGS. 1 and 2 with plug-in modules, heat pipe and spring clips removed;

FIG. 8 depicts an exemplary exterior heat pipe of the exemplary assembly in FIGS. 1 and 2;

FIG. 9 depicts an exemplary interior heat pipe of the exemplary assembly in FIGS. 1 and 2;

FIG. 10 depicts an exemplary chassis;

FIG. 11 depicts an enlarged section of the chassis in FIG. 10;

FIGS. 12 and 13 depict exemplary temperature gradients of the chassis in FIGS. 10 and 11;

FIGS. 14 and 15 depict sides of an exemplary 1×2 assembly connected to a support structure of a chassis;

FIG. 16 depicts a cage support structure for receiving and securely holding at least two high-speed assemblies (e.g., 1×2 assemblies) according to an embodiment;

FIG. 17 depicts an enlarged view of exemplary heat pipes;

FIG. 18 depicts an enlarged view of additional, exemplary heat pipes;

FIG. 19 depicts a simplified illustration of the exemplary cantilever motion of exemplary heat pipes; and

FIGS. 20 and 21 depict top and bottom views, respectively, illustrating the contact of heat pipes with plug-in modules to allow the transfer of thermal energy.

### DETAILED DESCRIPTION, INCLUDING EXEMPLARY EMBODIMENTS

Simplicity and clarity in both illustration and description are sought to effectively enable a person of skill in the art to make, use, and best practice embodiments disclosed herein in view of what is already known in the art. One skilled in the art will appreciate that various modifications and changes may be made to the specific embodiments described herein without departing from the spirit and scope of the disclosure. Thus, the specification and drawings are to be regarded as illustrative and exemplary rather than restrictive or all-encompassing, and all such modifications to the specific embodiments described herein are intended to be included within the scope of the disclosure. Yet further, unless otherwise noted, features disclosed herein may be combined together to form additional combinations that were not otherwise described or shown for purposes of brevity.

It should also be noted that one or more exemplary embodiments may be illustrated or described as a method or process. Although a method or process may be illustrated or described as an exemplary sequence (i.e., sequential), unless otherwise noted the steps in the sequence may also be performed in parallel, concurrently or simultaneously. In addition, the order of each formative step within a method or process may be re-arranged. An illustrated or described method or process may be terminated when completed, and may also include additional steps that are not illustrated or described herein if, for example, such steps are known by those skilled in the art.

As used herein the terms “high-speed” and “high-data rate” may be used interchangeably. As used herein, the term “embodiment” or “exemplary” mean an example that falls within the scope of the disclosure.

In the embodiments illustrated by the figures, and as explained herein, inventive assemblies and chassis are configured to create one or more thermal transfer paths to transfer thermal energy from a plug-in module, for example, to air. For example, one path may include the flow of thermal energy from a plug-in module (or another source of thermal energy) to a heat pipe, then to a support structure and on to a heat transfer surface (i.e., heat sink) that may include fins, and then on to a chassis and finally, via convection to air. A second path may include the flow of thermal energy from its source (plug-in module) to a heat pipe, then to a support structure, and then on to the top and bottom of a chassis (e.g., a chassis top lid and bottom wall), and finally to ambient air. In an embodiment, the second heat path may require one or more physical, thermal contacts (e.g., thermal pads) between the support structure and the bottom lid of a chassis.

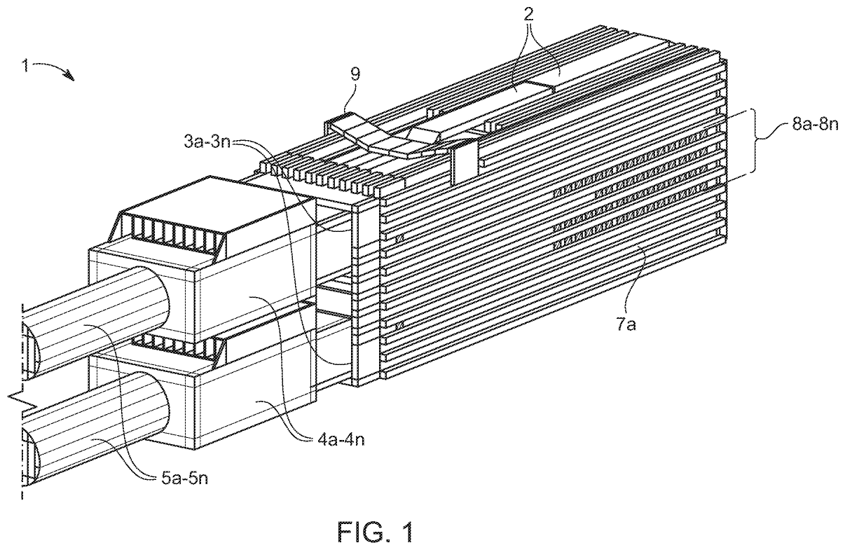

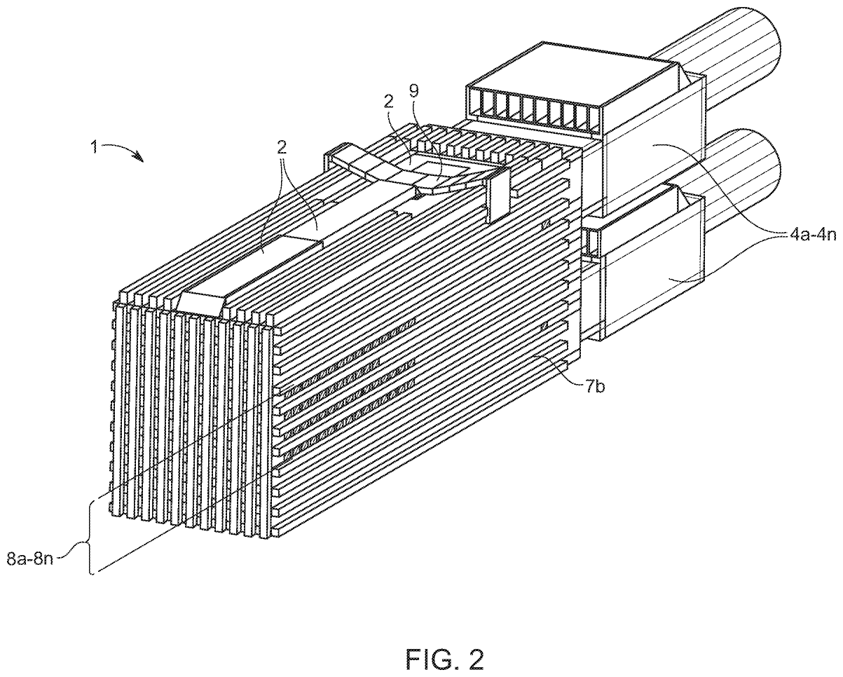

Referring now to FIGS. 1 and 2 there are depicted front and back views, respectively, of an exemplary, connector cage assembly 1 according to one embodiment. The connector cage assembly can be formed of a die cast process, which, as will be discussed below, allows for fins to be formed integrally with the structure. Other possible approaches include milling or extruding and forming side walls so that the fins are integral with the wall structure. Thus, using a die cast process to form the walls is believed beneficial but is not intended to be limiting unless otherwise noted. As shown, the assembly 1 may comprise a first or exterior, cantilevered thermal transfer element 2 (commonly referred to as a “heat pipe”) configured to transfer thermal energy (e.g., heat) generated by the assembly 1 and connected components during operation of the assembly 1 and the connected components. In an embodiment, the exterior heat pipe 2 may be composed of at least copper or a copper alloy, for example. In another embodiment the heat pipe 2 may be composed of a sealed copper wall, wick structure on the inside wall, and a working fluid.

Assembly 1 may be configured to transfer the thermal energy away from interior operating elements of the assembly 1 and interior connected components, such as plug-ins 4a to 4n, for example. As shown the assembly 1 may have one end (i.e., “front face”) configured with one or more openings or ports 3a to 3n (where “n” indicates a last port), each port configured to receive one or more connected components 4a to 4n (where “n” indicates a last connected component), such as plug-in modules, that in turn, may be configured to connect the assembly 1 to one or more telecommunications cables 5a to 5n (e.g., optical or electrical cables, again where “n” indicates a last cable), for example. The assembly also comprises a die cast rear wall (see FIG. 2). In embodiments, the cables, plug-in modules and assembly may be configured to transport high-speed data or high-data rate signals (e.g., signals greater than 56 Gigabits per second (Gbps) and in certain cases, between 112 Gbps and 224 Gbps).

In embodiments, the assembly 1 may be a connector cage assembly and may be composed of an aluminum alloy, for example. Though the assembly 1 is configured as receiving 2×1 double density (optical), small form-factor pluggable application (DDQ), printed circuit boards (PCB) (i.e., hereafter “plug-in modules”) this is merely exemplary, it being understood that the features and functions described herein may be incorporated into assemblies that include additional or fewer plug-in modules.

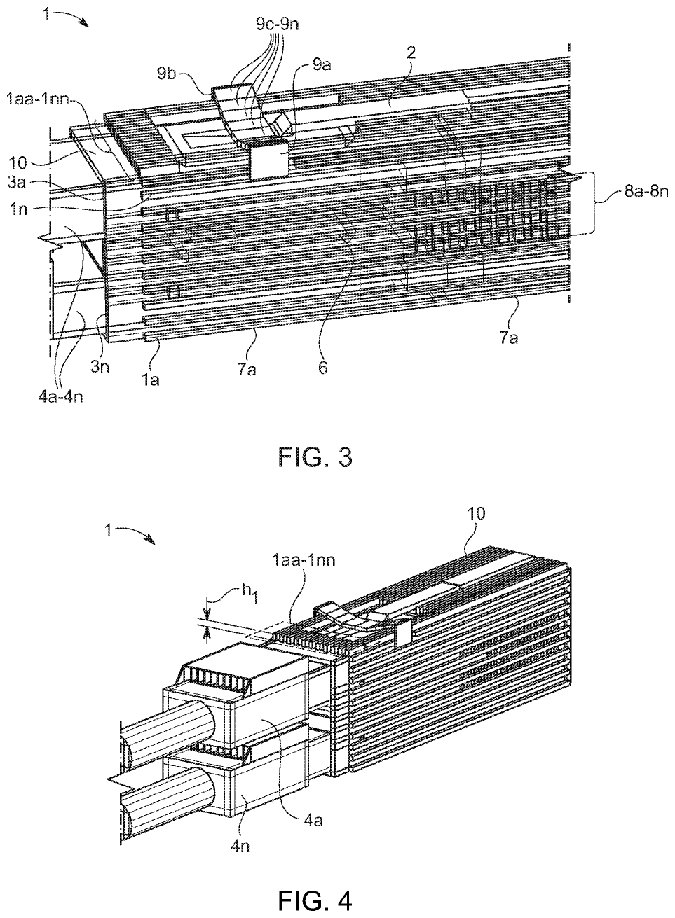

Referring now to FIG. 3 there is depicted another view of the exemplary assembly 1. As shown, the assembly 1 is depicted as transparent though this is merely for illustrative purposes to allow the reader to view some of the interior components of the assembly 1.

As shown, assembly 1 may include a second or interior cantilevered heat pipe 6 configured to transfer thermal energy generated by the connector cage assembly and the connected components during operation of the assembly and the connected components. The second heat pipe may also be composed of copper or a copper alloy, for example. As before, in another embodiment the heat pipe 6 may be composed of a sealed copper wall, wick structure on the inside wall, and a working fluid.

While the assembly 1 is depicted as including two heat pipes, this too is merely exemplary. In additional embodiments assemblies may include more than two heat pipes (e.g., multiple, interior heat pipes).

The assembly 1 may comprise exterior, die cast sidewalls 7a, 7b (only one of which is shown), an exterior die cast top wall 10 and an exterior die cast bottom wall (not shown in figures) that define a partially enclosed interior volume of the assembly 1.

In an embodiment, each of the die cast sidewalls 7a, 7b may comprise a plurality of fins 1a to 1n (where “n” indicates the last fin) and the die cast top wall 10 may also comprise a plurality of fins 1aa to 1nn (where “nn” indicates a last fin). Each fin 1a to 1n, 1aa to 1nn may function to increase the exterior surface area of a respective wall and may be formed to transfer thermal energy via conduction to air flowing around a respective fin, for example.

Each sidewall 7a, 7b may further include a plurality of vents or openings 8a to 8n (where “n” indicates a last vent). In embodiments, the vents 8a to 8n function to allow air surrounding the assembly 1 to pass through the interior volume of the assembly 1 in order to transfer (i.e., remove) thermal energy away from interior components, such as interior heat pipe 6, for example. Further, air that now contains transferred, thermal energy can exit out of the same vents 8a to 8n of sidewalls 7a, 7b.

If needed, the top wall 10 may also comprise a one or more vents in order to further transfer thermal energy away from interior components of the assembly, such as a 2×1 or 2×n assembly, for example.

Also shown in FIG. 3 is an exemplary, first flexible restraining clip 9. In an embodiment, end portions 9a, 9b of the clip 9 may be secured to the sidewalls 7a, 7b of the assembly and portions 9c to 9n (e.g., links) of the first flexible clip 9 (e.g., middle portion) may be bent towards, and may make contact with, the heat pipe 2 in order to restrain the movement of the heat pipe 2 away from interior components of the assembly 1 and from contacted components to insure heat transfer from the contacted components (e.g., modules 3a to 3n) to the heat pipe 2, for example (see FIG. 8).

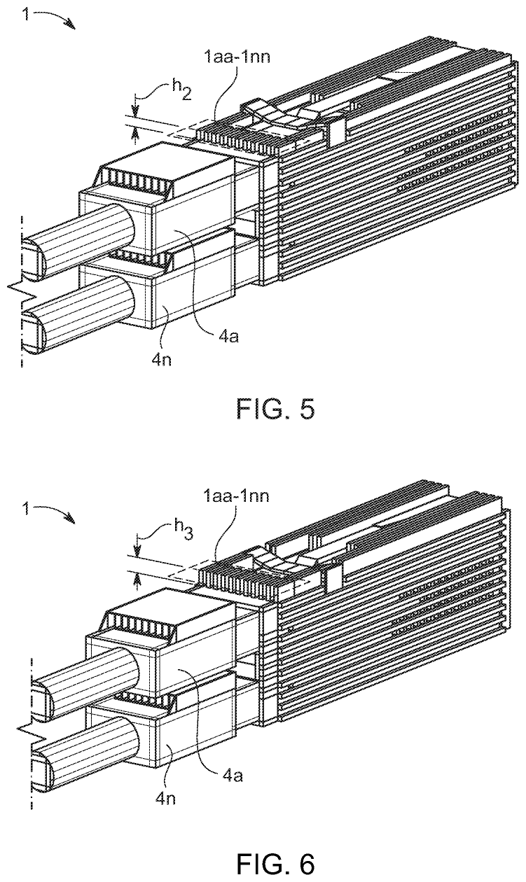

FIGS. 4 to 6 depict alternative configurations of the fins 1aa to 1nn of the top wall 10 of assembly 1. In embodiments, the height (measured in a perpendicular direction from the surface of the top wall 10) of the fins 1aa to 1nn may vary depending upon desired thermal transfer requirements and performance of the assembly 1, for example. For example, in FIG. 4 the height h₁ of the fins 1aa to 1nn may be 1.5 millimeters (mm) while, in comparison, the height of the fins 1a to 1n of sidewalls 7a, 7b may be 1.0 mm. In FIG. 5 the height h₂ of the fins 1aa to 1nn may be 2.5 mm while the height of the fins 1a to 1n of sidewalls 7a, 7b may be 1.0 mm Still further, in FIG. 6 the height h₃ of the fins 1aa to 1nn may be 3.5 mm while the height of the fins 1a to 1n of sidewalls 7a, 7b may be 1.0 mm Though the height of the fins 1aa to 1nn of top wall 10 in FIGS. 4 to 6 is given as 2.5 to 4.5 mm, this is merely exemplary in order to provide some examples of how the height of the fins 1aa to 1nn of the top wall 10 may be varied to attain desired heat transfer performance Naturally the height of the fins on the side walls may also vary, depending on space constraints.

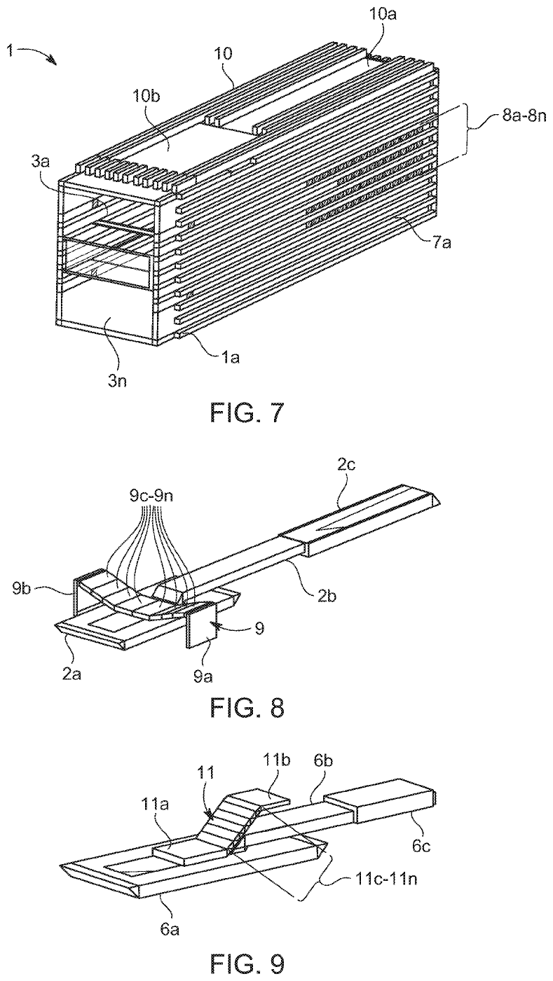

Referring now to FIG. 7 there is a view of the assembly 1 with the plug-in modules and heat pipes (among other components) removed. As shown, the top surface or wall 10 may comprise a surface indentation 10a configured to receive portions of the first cantilevered heat pipe 2 and an exterior opening 10b configured to receive additional portions of the first cantilevered heat pipe 2. In more detail and referring now to FIG. 8 there is depicted a view of the heat pipe 2. Though shown separately, it should be understood that the first cantilevered heat pipe 2 may be configured within the indentation 10a and opening 10b shown in FIG. 7, for example.

In more detail, exemplary heat pipe 2 may comprise a first or front portion 2a, a second or middle portion 2b and a third or rear portion 2c, for example, where the first portion 2a may be configured within opening 10b and the second and third portions 2b, 2c may be configured within indentation 10a, for example. In an embodiment the third portion 2c may be fixably connected to the die cast top wall 10 using a soldering process on one end, for example, while the first and second portions 2a, 2b may is not fixably connected to the die cast top wall 10 on an opposite end. Accordingly, the heat pipe 2 may function as a cantilever beam, being fixably connected to the top wall 10 on one end but not on the opposite end. Also shown in FIG. 8 is exemplary, flexible restraining clip 9. In an embodiment, clip 9 may be composed of a flexible material that functions to allow integral portions of the clip 9 to bend. In the embodiment depicted in FIG. 8 the portions are illustrated as a plurality of flexible links 9c to 9n where each link 9c to 9n may be configured to bend towards or away from the heat pipe 2, for example. However, this is merely one embodiment. In other embodiments the clip 9 may be an integral one-piece element comprising integral flexible portions that bend towards or away from heat pipe 2. Thus, though the heat pipe portions 2a, 2b may not be fixably connected to the assembly 1 their movement may be restrained by the force of clip 9, for example.

Further, flexible clip 9 may be configured to apply a force to heat pipe portion 2a such that the portion 2a makes contact with interior components of the assembly 1 or connected components (sometimes referred to as “biasing” the heat pipe) to create a thermal path to allow thermal energy to be transferred from the internal components or connected components to the first portion 2a. In one embodiment, the portion 2a may make physical contact with a plug-in module 4a to 4n within ports 3a to 3n, for example. Accordingly, the thermal path is created to allow thermal energy (heat) from a plug-in module generated during transmission of high-speed data signals, for example, to be transferred from a plug-in module (e.g., module 4a) to portion 2a. In one embodiment, heat transferred to portion 2a may then be further transferred through portion 2b and 2c to wall 10 of assembly 1 where it may then be transferred to air surrounding the assembly 1 by fins 1aa to 1nn (and 1a to 1n), for example, to complete the thermal path. Thus, it can be said that the heat pipe is thermally coupled to the plug-in module. In the embodiment just described it is assumed that the air surrounding the assembly 1 is at a lower temperature than the temperature of module 4a to 4n, thus allowing for the flow of thermal energy from a plug-in module to the surrounding air.

The second or interior, cantilevered heat pipe 6 may function similarly to exterior heat pipe 2. For example, referring now to FIG. 9 there is depicted a view of the second cantilevered heat pipe 6. Again, though shown separately, it should be understood that the heat pipe 6 may be configured within the interior of assembly 1 as shown in FIG. 3, for example.

In an embodiment, exemplary cantilevered heat pipe 6 may comprise a first or front portion 6a, a second or middle portion 6b and a third or rear portion 6c, for example, where the first portion 6a may be configured within an interior opening (not shown) and the second and third portions 6b, 6c may be configured within an interior indentation (not shown for clarity), for example. In an embodiment the third portion 6c may be fixably connected to an interior of the assembly 1 using a soldering process on one end, for example, while the first and second portions 6a, 6b are not fixably connected to the assembly 1 on an opposite end. Accordingly, the interior heat pipe 6 may function as a cantilever beam, being fixably connected to the assembly 1 on one end but not on the opposite end. Also shown in FIG. 9 is exemplary flexible restraining clip 11. In an embodiment, clip 11 may be composed of a flexible material that functions to allow integral portions of the clip 11 to bend. In the embodiment depicted in FIG. 9 the portions are illustrated as a plurality of flexible links 11c to 11n where each link 11c to 11n may be configured to bend towards or away from the heat pipe 6, for example. However, this is merely one embodiment. In other embodiments the clip 11 may be an integral one-piece element comprising integral, flexible portions that bend towards or away from heat pipe 6. Thus, though the heat pipe portions 6a, 6b may not be fixably connected to the assembly 1 their movement can be restrained by the force of clip 11, for example.

Further, clip 11 may be configured to apply a force to heat pipe portion 6a such that the portion 6a makes contact with interior components of the assembly 1 or connected components (again, sometimes referred to as “biasing” the heat pipe). In one embodiment, the portion 6a may make physical contact with a plug-in module (e.g., 4n) within ports 3a to 3n, for example, to create a thermal path to allow thermal energy (heat) to be transferred from plug-in module 4a to 4n (generated during transmission of high-speed data signals) to portion 6a. In one embodiment, heat transferred to portion 6a may then be further transferred through portion 6b and 6c to assembly 1 where it may then be transferred to the surrounding air by fins 1aa to 1nn and 1a to 1n, for example, of assembly 1, to complete the thermal path. In the embodiment just described it is assumed that the surrounding air is at a lower temperature than the temperature of module 4a to 4n, thus allowing for the flow of thermal energy from a plug-in module to the air.

In FIG. 8 the flexible clip 9 is illustrated as being configured perpendicular to the cantilever movement of heat pipe 2 while in FIG. 9 the flexible clip 11 is illustrated as being configured parallel to the cantilever movement of heat pipe 6, though this is merely exemplary. Said another way, the flexible clips 9, 11 may be, but are not required to be, configured to be perpendicular, or parallel, to the cantilever movement of heat pipes 2, 6, respectively, depending, for example, on the space available among other design parameters.

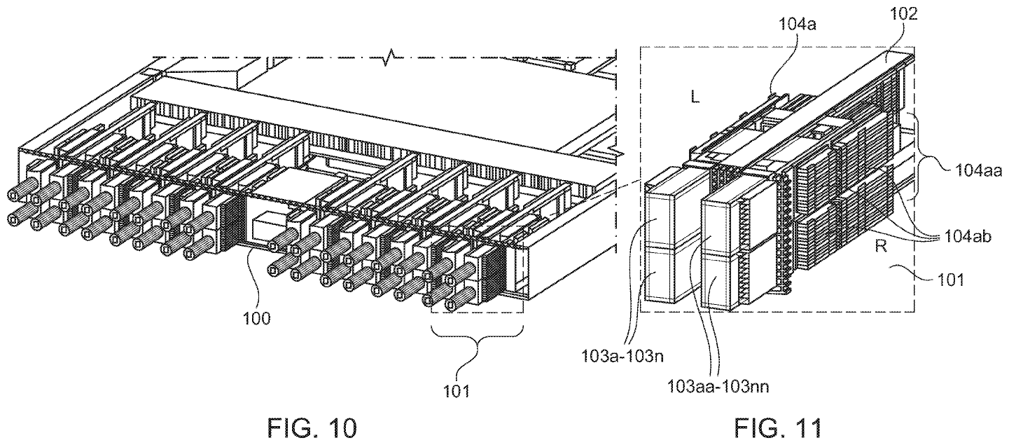

We refer now to FIGS. 10 and 11. FIG. 10 depicts a chassis 100 that may be configured to receive one or more assemblies (e.g., extruded or die cast assemblies) that transport high-speed differential data signals via cables (optical or electrical cables; not shown), while FIG. 11 depicts an enlarged view of two of the assemblies. For the sake of clarity, the assemblies are labeled left (L) and right (R) in FIG. 11 to denote that in the view shown in FIG. 11 one assembly is to the left of the support structure 102 and the other assembly is to the right of the structure 102.

As noted previously, inventive chassis may be configured to create one or more thermal transfer paths to transfer thermal energy from a plug-in module, for example, to air. Set forth herein is a description of one path that may allow thermal energy to flow from a plug-in module (or another source of thermal energy) to a heat pipe, then to a support structure and on to a heat transfer surface (i.e., heat sink) that may include fins, and then on to a chassis and finally, via convection to air. However, an inventive chassis may be configured to create a second path that allows the flow of thermal energy from a source (plug-in module) to a heat pipe, then to a support structure, and then on to the top and bottom of a chassis (e.g., a chassis top lid and bottom wall), and finally to ambient air. In an embodiment, such a second heat path may require one or more physical, thermal contacts (e.g., thermal pads) between the support structure and the bottom lid of a chassis.

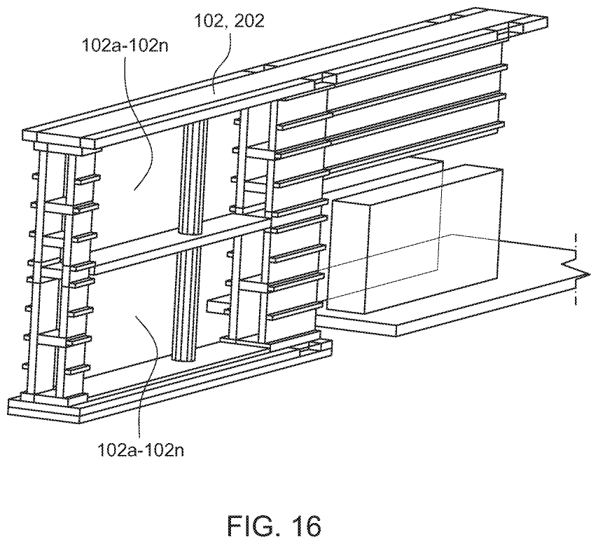

Continuing, FIG. 11 depicts an enlarged section 101 of the chassis 100 depicting a support structure 102 configured to receive and securely hold at least assembles (“L” and “R”) (see, for example, openings 102a to 102n in FIG. 16). FIG. 11 also depicts a cage structure 104aa for assembly R. In embodiments, structure 104aa may be configured to conduct and transfer thermal energy (i.e., it functions as a heat sink). Optionally, structure 104aa may comprise a plurality of thermal transfer elements 104ab (e.g., fins) that function to increase the exterior surface area of the cage structure 104aa and may be formed to transfer thermal energy via conduction to air flowing around a respective fin, for example. It should be understood that both assembles in FIG. 11 (e.g., R and L), each on an opposite side of the support structure 102 may include such thermal transfer elements though the elements for cage structure 104a of assembly L are mostly hidden from view (but see similar elements 204ab in FIG. 15).

In embodiments, structure 104aa may be composed of copper, copper alloy, aluminum or aluminum alloy for example depending on a desired cost and thermal requirements.

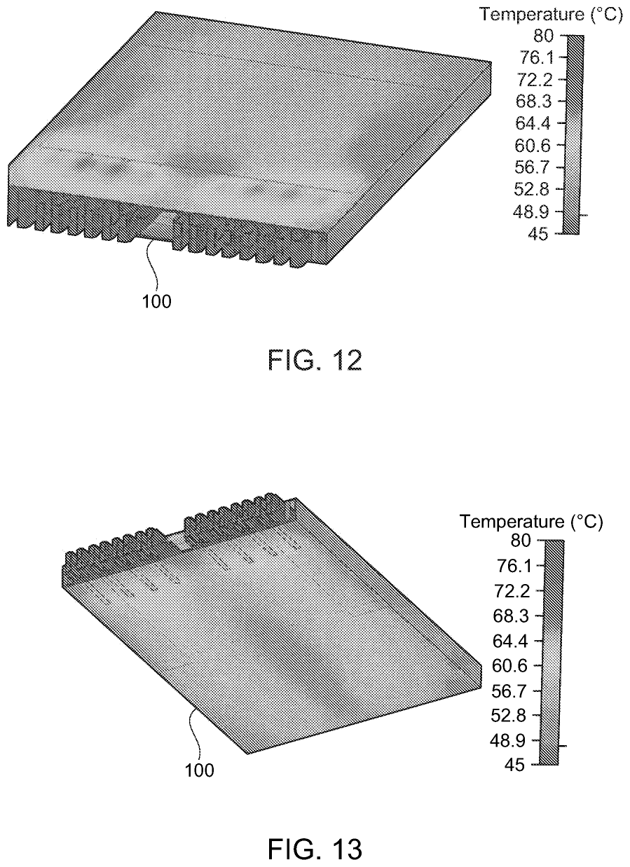

It is expected that during transmission of high-speed data signals through plug-in modules that the temperature of the connected plug-in modules and internal components of the chassis 100 may increase. Accordingly, it is believed that the addition of heat pipes that create thermal transfer paths may help transfer thermal energy from such plug-in modules to the chassis. Exemplary temperature gradients for sides of a sample chassis 100 that incorporates exemplary heat pipes are depicted in FIGS. 12 and 13 (e.g., top side and bottom side, where the darker portions (on the scale) represent a higher or lower temperatures than the lighter portions). For reference, in these gray-scale images, the darker areas near the front of the chassis are slightly higher on the temperature scale, while the darker areas on the center, left and right of the chassis are on the lower side of the temperature scale.

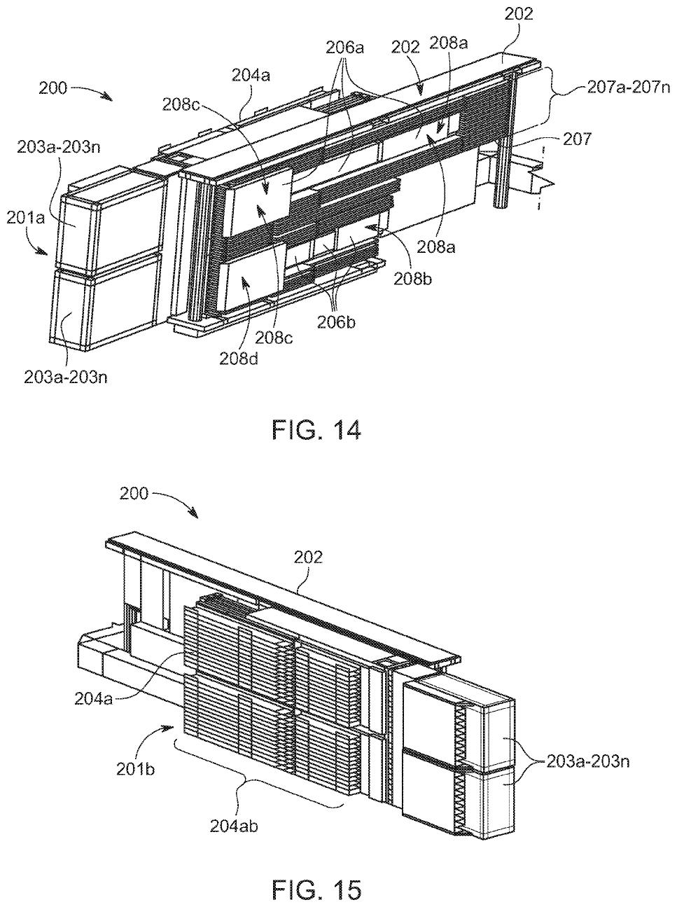

Referring now to FIGS. 14 and 15 there are depicted sides 201a, 201b of a 1×2 assembly 200 that is similar to the assembly L in FIG. 11. In more detail, FIG. 14 depicts one side 201a of the assembly 200 while FIG. 15 depicts an opposite side 201b of the same assembly 200, for example.

Referring first to FIG. 14, in an embodiment the assembly may comprise a heat transfer surface 207 (e.g., a heat sink) and one or more cantilevered heat pipes 206a, 206b received in the heat sink 207. In an embodiment, the cantilevered heat sink 207 and heat pipes 206a, 206b may be composed of at least copper or a copper alloy, for example. Alternatively, the heat pipes 206a, 206b 2 may be composed of a sealed copper wall, wick structure on the inside wall, and a working fluid.

The surface 207 may comprise a plurality of first fins 207a to 207n (only a few are labeled in FIG. 14), where each first fin may function to increase the exterior surface area of the surface 207 and may be formed to transfer thermal energy via convection to air flowing around a respective first fin, for example.

Further, one end section 208a, 208b of each heat pipe 206a, 206b may be fixably connected to the heat transfer surface 207 and/or to structure 202 (e.g., via soldering) while the other (opposite) end sections 208c, 208d of each heat pipe 206a, 206b may not be connected to surface 207. Accordingly, the heat pipes 206a, 206b may function as a cantilever beam, being fixably connected to the surface 207 on one end but not on an opposite end. Though not connected to surface 207, end sections 208c, 208d may be configured to contact plug-in modules 203a to 203n transporting high-speed data signals positioned in ports of the assembly to create a thermal path in order to transfer thermal energy from a plug-in module to the contacted end section and eventually to the support structure 202.

In more detail, as end sections 208c, 208d make contact with plug-in modules 203a to 203n, a thermal path is created that transfers thermal energy from a plug-in module 203a to 203n to end sections 208c, 208d, which flows towards fixed end sections 208a, 208b and continues flowing on to surface 207 and first fins 207a to 207n on structure 202. Accordingly, thermal energy may be transferred from a plug-in module 203a to 203n to the structure 202. Further, because structure 202 may be physically connected to a chassis (e.g., chassis 100) it can be said that the configuration described above and shown in the figures provides for the transfer of thermal energy from plug-in modules 203a to 203n to a chassis.

Referring now to FIG. 15, an opposite side 201b of the assembly 200 is depicted. As shown, the exemplary assembly 200 may comprise a cage structure 204a that may include a plurality of second, thermal transfer elements 204ab (e.g., “second” fins), where each second fin may function to increase the exterior surface area of structure 204a and may be formed to transfer thermal energy via convection to air flowing around a respective second fin, for example. In embodiments, the physical dimensions and area of the structure 204a may vary depending on a desired thermal transfer performance.

As noted previously, FIG. 16 depicts a support structure (e.g., 102, 202) comprising openings 102a to 102n in structure 202, each opening 102a to 102n configured to receive and securely hold at least two 1×2 assemblies (e.g., L and R in FIG. 11 or 200 in FIGS. 14 and 15). In FIG. 16, there are two openings 102a to 102n and thus a total of four assemblies may be received. Though 1×2 assemblies are depicted in the figures, it should be understood that exemplary support structures may be configured to receive a plurality of different sized assemblies other than 1×2 assembles.

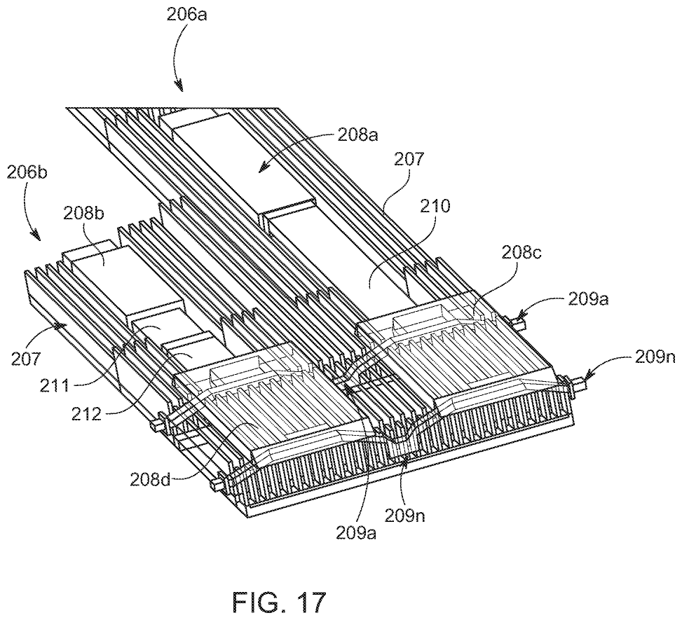

FIG. 17 depicts an enlarged view of exemplary heat pipes similar to heat pipes 206a, 206b of assembly 200 in FIG. 14. In an embodiment, a surface or wall 207 may comprise one or more surface indentations configured to receive first sections of cantilevered heat pipes and one or more exterior openings configured to receive second, additional sections of the cantilevered heat pipes. For example, a first surface indentation of the indentations is configured to receive first sections of a first cantilevered heat pipe and a first opening of the openings is configured to receive second, additional sections of the first cantilevered heat pipe. In more detail, the surface 207 may comprise a first surface indentation (not shown) configured to receive first sections 208a, 210 of the heat pipe 206a and an exterior, first opening (not shown) configured to receive second, additional section 208c of the heat pipe 206a.

Similarly, the surface or wall 207 may comprise a second surface indentation (not shown) configured to receive first sections 208b, 211, 212 of the second cantilevered heat pipe 206b and an exterior, second opening (not shown) configured to receive a second, additional section or sections 208d of the second cantilevered heat pipe 206b.

Yet further, as explained previously one end section 208a, 208b (a “first” section) of each cantilevered heat pipe 206a, 206b may be fixably connected to the heat transfer surface 207 while the other (opposite, or “second”) end section 208c, 208d of each heat pipe 206a, 206b may not be connected to surface 207, though end sections 208c, 208d may make contact with spring structures 209a to 209n. Accordingly, the heat pipes 206a, 206b may function as a cantilever beam. Though not connected to surface 207, end sections 208c, 208d may be configured to contact plug-in modules 203a to 203n positioned in ports of the assembly (not shown in FIG. 17) by forces applied by flexible spring structures 209a to 209n in order to transfer thermal energy from a plug-in module 203a to 203n to end sections 208c, 208d and eventually to a chassis, for example.

In an embodiment, a flexible spring structure 209a to 209n for each cantilevered heat pipe may be configured to restrain movement of a respective, cantilevered heat pipe 206a, 206b by applying a force to a section of a respective cantilevered heat pipe such that the section contacts with the interior components of the assembly or the connected components (e.g., plug-ins) to create a thermal path to allow thermal energy to be transferred. In an embodiment, a clip 209a to 209n may be composed of a flexible material that functions to allow integral portions of the clip to bend towards or away from a heat pipe 206a, 206b.

In more detail, ends of each exemplary flexible spring structure 209a to 209n may be fixably connected to the surface 207 by solder, for example. Further, middle portions of each structure 209a to 209n may be configured bent towards end sections 208c, 208d in order to apply a force to heat pipe end sections 208c, 208d such that the end sections 208c, 208d make contact with interior components of an assembly or connected components (again, sometimes referred to as “biasing” the heat pipe), such as plug-in modules 203a to 203n. As configured, each spring structure 209a to 209n may be fixed on one geometric axis but may move or flex on the other two geometric axes.

Because end sections 208c, 208d may make physical contact with a plug-in module 203a to 203n, a thermal path may be created (heat) to allow thermal energy to be transferred from the plug-in modules (that are generating high-speed data signals) modules 203a to 203n to end sections 208c, 208d. In one embodiment, heat transferred to end sections 208c, 208d may then be further transferred to middle sections 210, 211, 212, respectively of each heat pipe 206a, 206b and then to fixed end sections 208a, 208b, for example. In an embodiment, such transferred thermal energy may then be transferred to the surrounding air by fins 207a to 207n of surface 207 and by support structure 202 that is connected to surface 207 to complete the thermal path, for example. In the embodiment just described it is assumed that the surrounding air is at a lower temperature than the temperature of modules 203a to 203n, thus allowing for the flow of thermal energy from a plug-in module to the air.

To receive and accommodate the structures 209a to 209n, the surface 207 may include portions without a fin (e.g., cut-outs, i.e., openings between the fin structures 207a to 207n).

Though two flexible spring structures 209a to 209n for each end section 208c, 208d are depicted in FIG. 17 this is merely exemplary. The number of structures 209a to 209n may be greater or less than two depending on the force required to be applied to a particular heat pipe or based on other constraints (e.g., the surface area available on surface 207). Further, the structures 209a to 209n may be configured to apply a force to end sections 208c, 208d at different positions other than those shown in FIG. 17 provided that such positioning provides sufficient force to be applied on to an end section 208c, 208d by structure 209a to 209n. Still further, while FIG. 17 depicts the flexible spring structures 209a to 209n configured perpendicular to the cantilever movement of heat pipes 206a, 206b this is merely exemplary. Said another way, the flexible spring structures 209a to 209n may be configured perpendicular, or parallel, to the cantilever movement of heat pipes 206a, 206n, respectively.

In addition to structures 209a to 209n, to ensure sufficient heat transfer between a plug-in module and a heat pipe 206a, 206b the plug-in module should be appropriately aligned with end section 208c, 208d, for example.

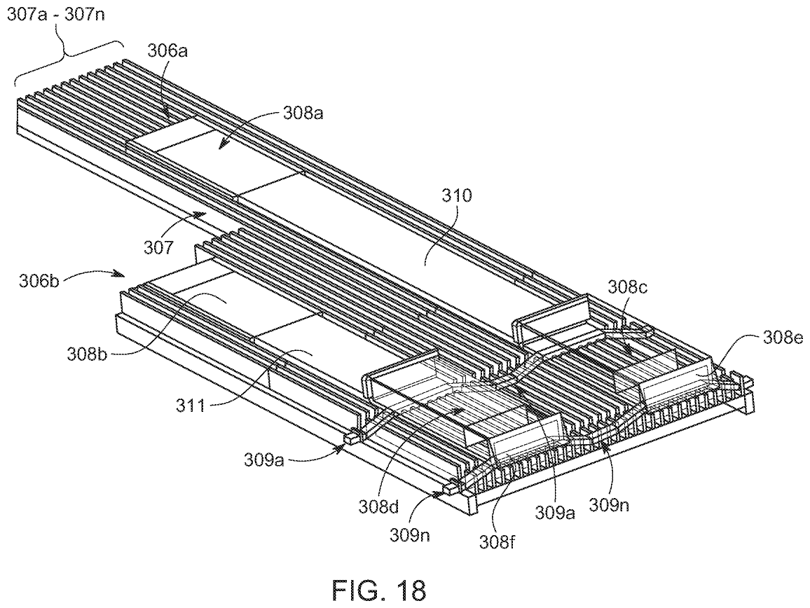

Referring now to FIG. 18 there is depicted an enlarged view of exemplary heat pipes 306a, 306b that may be composed of at least copper or a copper alloy, for example. As before, alternatively, the heat pipes 306a, 306b may be composed of a sealed copper wall, wick structure on the inside wall, and a working fluid.

In an embodiment, a surface or wall 307 may comprise a first surface indentation (not shown) configured to receive first sections 308a, 310 of the first heat pipe 306a and an opening (not shown) configured to receive second sections 308c, 308e of the first heat pipe 306a Similarly, the surface or wall 307 may comprise a second surface indentation (not shown) configured to receive first sections 308b, 311 of the second heat pipe 306b and a second opening (not shown) configured to receive second sections 308d, 308f of the second heat pipe 306b.

Similar to other embodiments, the end or first sections 308a, 308b of each heat pipe 306a, 306b may be fixably connected to the heat transfer surface 307 (e.g., by soldering) while the other (opposite or “second”) end sections 308c, 308e and 308d, 308f of each heat pipe 306a, 306b may not be connected to surface 307, though end sections 308c, 308e and 308d, 308f may make contact with one or more spring structures 309a to 309n. Accordingly, the heat pipes 306a, 306b may function as a cantilever beam. Though not connected to surface 307, end sections 308c, 308e and 308d, 308f may be configured to contact plug-in modules positioned in ports of the assembly (not shown in FIG. 18) by forces applied by one or more flexible spring structures 309a to 309n in order to transfer thermal energy from a plug-in module to end sections 308c, 308e and 308d, 308f and eventually to a chassis.

In an embodiment, ends of each exemplary flexible spring structure 309a to 309n may be fixably connected to the surface 307 by solder, for example. Further, middle portions of each structure 309a to 309n may be configured bent towards end sections 308c, 308e and 308d, 308f, respectively, in order to apply a force to heat pipe end sections 308c, 308e and 308d, 308f such that the end sections 308c, 308e and 308d, 308f make contact with interior components of the assembly or connected components (again, sometimes referred to as “biasing” the heat pipe), such as plug-in modules. As configured, each spring structure 309a to 309n may be fixed on one geometric axis but may move or flex on the other two geometric axes.

Because end sections 308c, 308e and 308d, 308f may make physical contact with a plug-in module, thermal energy (heat) from the plug-in module(s) generated during transmission of high-speed data signals may be transferred from the plug-in modules to end sections 308c, 308e and 308d, 308f. In one embodiment, heat transferred to end sections 308c, 308e and 308d, 308f may then be further transferred to middle sections 310 of heat pipe 306a, and section 311 of heat pipe 306b and eventually to end sections 308a, 308b, for example. In an embodiment, such transferred thermal energy may then be transferred to the surrounding air by fins 307a to 307n of surface 307 and by a support structure (not shown) that is connected to surface 307, for example. In the embodiment just described it is assumed that the surrounding air is at a lower temperature than the temperature of the plug-in modules, thus allowing for the flow of thermal energy from a plug-in module to the air.

In addition to structures 309a to 309n, to ensure sufficient heat transfer between a plug-in module and a heat pipe 306a, 306b the plug-in module should be appropriately aligned with end sections 308c, 308e and 308d, 308f, for example.

To receive and accommodate the structures 309a to 309n, the surface 307 may include portions without a fin. Said another way, in an embodiment the surface 307 may be configured with cut-outs (i.e., spaces) between fin structures 307a to 307n to receive the one or more spring structures 309a to 309n.

Though two flexible spring structures 309a to 309n are depicted in FIG. 18 this is merely exemplary. The number of structures 309a to 309n may be greater or less than two depending on the force required to be applied to a particular heat pipe or based on other constraints (e.g., the surface area available on surface 307). Further, the structures 309a to 309n may be configured to apply a force to end sections 308c, 308e and 308d, 308f at different positions other than those shown in FIG. 18 provided that such positioning provides sufficient force on to an end section 308c, 308e and 308d, 308f by structure 309a to 309n. Still further, while FIG. 18 depicts the flexible spring structures 309a to 309n configured perpendicular to the cantilever movement of heat pipes 306a, 306b this is merely exemplary. Said another way, the flexible spring structures 309a to 309n may be configured perpendicular, or parallel, to the cantilever movement of heat pipes 306a, 306n, respectively.

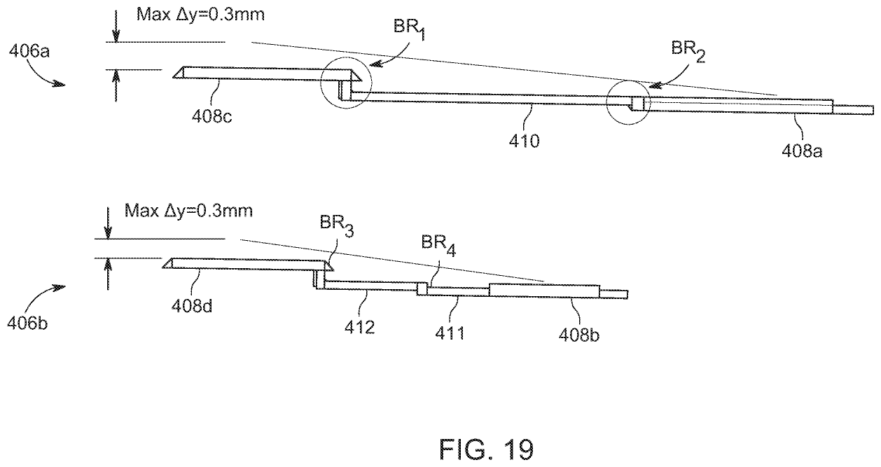

Referring now to FIG. 19 there is depicted a simplified illustration of exemplary cantilever motion of exemplary heat pipes 406a, 406b similar to the heat pipes in FIGS. 17 and 18, for example. In an embodiment, the heat pipes 406a, 406b may be composed of at least copper or a copper alloy, for example or alternatively, a sealed copper wall, wick structure on the inside wall, and a working fluid.

In an embodiment, the middle section 410 of heat pipe 406a may be longer (e.g., 68 mm) than middle sections 411, 412 (e.g., 48 mm) of heat pipe 406b. Accordingly, though one heat pipe 406a may have a longer length than the other heat pipe 406b, in an embodiment, each heat pipe 406a, 406b may be configured with a minimum bend radius at least at points BR₁, BR₂, BR₃ and BR₄, respectively, to allow the same amount of deflection (e.g., 0.3 mm) that allows an end section 408c, 408d to make contact with a plug-in module (not shown), for example, to transfer thermal energy from the plug-in modules to the end section 408c, 408d and eventually to a chassis, for example.

In more detail, the inventors discovered that bends in a heat pipe may negatively impact the thermal energy transfer performance of the heat pipe. To control such thermal transfer performance, in embodiments, a minimum bend radius for points along a heat pipe may be configured. Because the length of heat pipes 406a and 406b differ, the minimum bend radius at points BR₁, BR₂, BR₃, and BR₄ may be different (i.e., different values). Preferably the bending of the heat pipe is managed in a gradual manner so that abrupt steps that might interfere with the performance of the heat pipe are avoided.

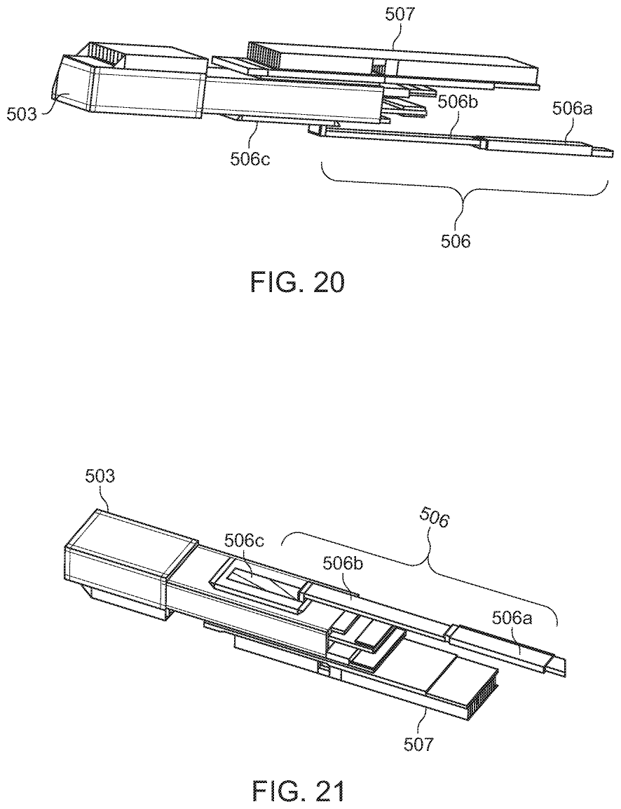

In the discussion herein it has been mentioned that an end portion or section of a heat pipe may make contact with a plug-in module to transfer thermal energy away from the plug-in module. Referring now to FIGS. 20 and 21 there are depicted top and bottom views, respectively, of such contact. As shown, an exemplary, cantilevered heat pipe 506 may comprise an end portion or section 506c that may be configured to make contact with a plug-in module 503 that, in turn, may be configured to transport high-speed data signals, for example, it being understood that end section or portion 506c is not fixably connected to a heat transfer structure 507 (e.g., a heat sink composed of e.g., a heat sink composed of a conductive material, such as an aluminum) of an assembly, while end section 506a is connected to the another heat transfer structure (not shown). Middle portion 506b is also shown. End sections in embodiments of the invention that are not fixably attached to a structure may be “pre-bent” such that they lay flat against a heat-producing structure when connector assemblies are fully constructed and the end section is deflected.

While benefits, advantages, and solutions have been described above with regard to specific embodiments of the present invention, it should be understood that any component(s) that may cause or result in such benefits, advantages, or solutions to become more pronounced are not to be construed as a critical, required, or an essential feature or element of any or all the claims appended to the present disclosure or that result from the present disclosure.

Further, the disclosure provided herein describes features in terms of specific exemplary embodiments. However, numerous additional embodiments and modifications within the scope and spirit of the appended claims will occur to persons of ordinary skill in the art from a review of this disclosure and are intended to be covered by the disclosure and appended claims. Accordingly, it is intended that all such additional embodiments, modifications and equivalents of the subject matter recited in the claims appended hereto are included as permitted by applicable law. Moreover, any combination of the above-described components in all possible variations thereof is encompassed by the disclosure unless otherwise indicated herein or otherwise clearly contradicted by context.

1. A connector cage assembly comprising:
die cast sidewalls, a die cast top wall and a die cast bottom wall and a die cast rear wall that defines a partially enclosed interior volume of the connector cage assembly;
a front face having one or more ports, each port configured to receive one or more connected components configured to transport high-speed data signals; and
a first cantilevered heat pipe configured to transfer thermal energy generated by the connector cage assembly and the connected components during operation of the assembly and the connected components.

2. The assembly as in claim 1 further comprising a second cantilevered heat pipe configured to transfer thermal energy generated by the connector cage assembly and the connected components during operation of the assembly and the connected components.

3. The assembly as in claim 1 wherein the first cantilevered heat pipe is composed of at least copper or a copper alloy.

4. The assembly as in claim 2 wherein the second cantilevered heat pipe is composed of at least copper or a copper alloy.

5. The assembly as in claim 1 wherein the high-speed data signals comprise at least signals greater than 56 gigabits (Gbps).

6. The assembly as in claim 1 wherein the high-speed data signals comprise signals between 112 Gbps and 224 Gbps.

7. The assembly as in claim 1 wherein the connector cage assembly is composed of an aluminum alloy.

8. The assembly as in claim 1 wherein the connected components comprise 2×1 double density (DDQ), small form-factor plug-in modules.

9. The assembly as in claim 1 wherein the die cast sidewalls comprise a plurality of fins to transfer thermal energy to air flowing around a respective fin.

10. The assembly as in claim 1 wherein the die cast top wall comprises a plurality of fins to transfer thermal energy to air flowing around a respective fins.

11. The assembly as in claim 10 wherein a height of the fins of the die cast top wall varies depending upon desired thermal transfer requirements and performance of the assembly.

12. The assembly as in claim 10 wherein a height of the fins of the top wall is 2.5 to 4.5 millimeters.

13. The assembly as in claim 1 wherein the die cast sidewalls comprise a plurality of vents to allow air surrounding the assembly to pass through the assembly to transfer thermal energy away from interior components.

14. The assembly as in claim 1 further comprising a first restraining clip to restrain the movement of the first cantilevered heat pipe and to create a thermal path to allow thermal energy to be transferred from the connected components to the first cantilevered heat pipe.

15. The assembly as in claim 1 wherein the die cast top wall comprises a surface indentation configured to receive portions of the first cantilevered heat pipe and an exterior opening configured to receive additional portions of the first cantilevered heat pipe.

16. The assembly as in claim 1 wherein the first cantilevered heat pipe comprises a first portion, a second portion and a third portion, where the first portion is configured within an opening of the die cast top wall and the second and third portions are configured within a surface indentation of the die cast top wall.

17-18. (canceled)

19. The assembly as in claim 2 further comprising a second restraining clip to restrain the movement of the second cantilevered heat pipe and to create a thermal path to allow thermal energy to be transferred from the connected components to the second cantilevered heat pipe.

20. A chassis configured to receive one or more assemblies, the chassis comprising: a support structure configured to receive and securely hold the assemblies, where each assembly comprises:
a heat sink comprising a plurality of first fins to transfer thermal energy to air flowing around a respective first fin,
one or more cantilevered heat pipes received in the heat sink, each heat pipe comprising a section fixably connected to the heat sink and another section that is not connected to the heat sink, wherein the section that is not connected to the heat sink is configured to contact a plug-in module transporting high-speed data signals to create a thermal path to transfer thermal energy from the plug-in module to the contacted end section and then to the support structure,
a cage structure comprising a plurality of second fins to transfer thermal energy to air flowing around a respective second fin.

21-23. (canceled)

24. The chassis as in claim 20 wherein the one or more cantilevered heat pipes are composed of at least copper or a copper alloy.

25. The chassis as in claim 24 wherein each of the one or more cantilevered heat pipes are configured with a minimum bend radius to contact with the plug-in module.

26-30. (canceled)
